(19) United States
(12) Patent Application Publication
(10) Pub. No.: US 2024/0258398 A1
(43) Pub. Date: Aug. 1, 2024

(54) HIGH ELECTRON MOBILITY TRANSISTOR AND METHOD OF MANUFACTURING THE SAME

(71) Applicant: SAMSUNG ELECTRONICS CO., LTD., Suwon-si (KR)

(72) Inventors: Junhyuk PARK, Suwon-si (KR); Jaejoon OH, Suwon-si (KR); Injun HWANG, Suwon-si (KR); Boram KIM, Suwon-si (KR); Jongseob KIM, Suwon-si (KR); Joonyong KIM, Suwon-si (KR)

(73) Assignee: SAMSUNG ELECTRONICS CO., LTD., Suwon-si (KR)

(21) Appl. No.: 18/381,945

(22) Filed: Oct. 19, 2023

(30) Foreign Application Priority Data
Jan. 30, 2023 (KR) 10-2023-0011859

(51) Int. Cl. H01L 29/47; H01L 29/20; H01L 29/40; H01L 29/66; H01L 29/778

(52) U.S. Cl. CPC H01L 29/475; H01L 29/2003; H01L 29/401; H01L 29/66462; H01L 29/7786

(57) ABSTRACT

A high electron mobility transistor (HEMT) includes a substrate, a channel layer on the substrate, a barrier layer on the channel layer, a p-type gallium nitride (GaN) layer on the barrier layer, an n-type interfacial layer on the p-type GaN layer, and a gate electrode on the n-type interfacial layer.

### CROSS-REFERENCE TO RELATED APPLICATIONS

This application is based on and claims priority under 35 U.S.C. § 119 to Korean Patent Application No. 10-2023-0011859, filed on Jan. 30, 2023, in the Korean Intellectual Property Office, the disclosure of which is incorporated by reference herein in its entirety.

### BACKGROUND

### 1. Field

The disclosure relates to a high electron mobility transistor and a method of manufacturing the same, whereby a gate leakage current may be reduced.

### 2. Description of the Related Art

A nitride semiconductor device may be used as, for example, a power device used for power control. One of the power devices is a high electron mobility transistor (HEMT). The HEMT may include a channel layer and a barrier layer on the channel layer and may further include a two-dimensional electron gas (2DEG) used as a carrier in the channel layer. As the 2DEG is used as the carrier, the electron mobility of the HEMT is greater than that of a general transistor. The HEMT may include a compound semiconductor having a wide band gap. Thus, a breakdown voltage of the HEMT may be greater than that of the general transistor. The breakdown voltage of the HEMT may increase proportionally to a thickness of a compound semiconductor layer including the 2DEG (e.g., a gallium nitride (GaN) layer).

The HEMT may include semiconductor layers having different band gaps. In the HEMT, a semiconductor layer having a large band gap may serve as a donor. The 2DEG may be formed on a semiconductor layer having a small band gap by the semiconductor layer having the large band gap. In the HEMT, the 2DEG may be used as a channel.

### SUMMARY

Provided is a high electron mobility transistor capable of reducing a gate leakage current.

In addition, provided is a method of manufacturing a high electron mobility transistor capable of reducing a gate leakage current.

Additional aspects will be set forth in part in the description which follows and, in part, will be apparent from the description, or may be learned by practice of the presented embodiments of the disclosure.

According to an aspect of the disclosure, a high electron mobility transistor (HEMT) may include a substrate, a channel layer on the substrate, a barrier layer on the channel layer, a p-type gallium nitride (GaN) layer on the barrier layer, an n-type interfacial layer on the p-type GaN layer, and a gate electrode on the n-type interfacial layer.

The n-type interfacial layer may include a nitrogen vacancy.

The n-type interfacial layer may include a thickness of about 1 nm to about 5 nm.

The n-type interfacial layer may directly contact the p-type GaN layer.

The n-type interfacial layer and the gate electrode may form a Schottky contact.

The HEMT may include a silicon nitride (SiN) layer between the n-type interfacial layer and the gate electrode.

The SiN layer may include a composition ratio of silicon to nitrogen that is greater than 1.

The SiN layer may include a thickness of about 1 nm to about 500 nm.

The gate electrode may include at least one of titanium (Ti), titanium nitride (TiN), titanium aluminide (TiAl), or tungsten (W).

The channel layer may include gallium nitride (GaN), indium gallium nitride (InGaN), or aluminum gallium nitride (AlGaN).

The barrier layer may include aluminum nitride (AlN), AlGaN, aluminum indium nitride (AlInN), or aluminum indium gallium nitride (AlInGaN).

According to an aspect of the disclosure, a method of manufacturing an HEMT may include depositing a channel layer on a substrate, depositing a barrier layer on the channel layer, depositing a p-type GaN layer on the barrier layer, depositing a silicon nitride (SiN) layer on the p-type GaN layer, forming an n-type interfacial layer between the p-type GaN layer and the SiN layer by performing heat treatment on the SiN layer, and forming a gate electrode on the n-type interfacial layer.

The heat treatment may be performed at a temperature of about 400° C. or higher.

The n-type interfacial layer may include a nitrogen vacancy.

The n-type interfacial layer may include a thickness of about 1 nm to about 5 nm.

The n-type interfacial layer may directly contact the p-type GaN layer.

The method may include, prior to the forming of the gate electrode, removing the SiN layer.

The method may include forming a through-hole through which the p-type GaN layer is exposed by partially etching the SiN layer.

According to an aspect of the disclosure, a HEMT may include a substrate, a channel layer on the substrate, a barrier layer on the channel layer, a two-dimensional electron gas (2DEG) layer formed between the channel layer and the barrier layer, a p-type GaN layer on the barrier layer, an n-type interfacial layer on the p-type GaN layer, and a gate electrode on the n-type interfacial layer.

The 2DEG layer may include an opening and wherein a width of at least one of the p-type GaN layer, the n-type interfacial layer, or the gate electrode may correspond to a width of the opening of the 2DEG layer.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view of a high electron mobility transistor according to an embodiment;

FIG. 2 is a cross-sectional view an example of the high electron mobility transistor of FIG. 1 that further includes a silicon nitride layer according to an embodiment;

FIG. 3 is a cross-sectional view of a modified example of the silicon nitride layer of FIG. 2 according to an embodiment; and

FIGS. 4, 5, 6, 7 and 8 are cross-section views illustrating a method of manufacturing a high electron mobility transistor according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects.

As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, or c,” should be understood as including only a, only b, only c, both a and b, both a and c, both b and c, or all of a, b, and c.

Hereinafter, a high electron mobility transistor and a method of manufacturing the same according to various embodiments will be described in detail with reference to the accompanying drawings. In the drawings, like reference numerals denote like components, and sizes of components in the drawings may be exaggerated for convenience of explanation. Terms such as first, second, and the like may be used to describe various elements, but the elements should not be limited to those terms. These terms may be used to distinguish one element from another element.

Singular forms include plural forms unless apparently indicated otherwise contextually. When a portion is referred to as “comprises” a component, the portion may not exclude another component but may further include another component unless stated otherwise. In addition, the size or thickness of each component in the drawings may be exaggerated for clarity of a description. Moreover, when it is described that a certain material layer is present on a substrate or another layer, the material layer may be present in direct contact with the substrate or the other layer or a third layer may be present therebetween. In the following embodiment of the disclosure, a material of each layer may be an example and thus another material may be used.

The term used herein such as “unit” or “module” indicates a unit for processing at least one function or operation, and may be implemented in hardware, software, or in a combination of hardware and software.

Certain executions described here are examples, not limiting the technical scope of the disclosure in any way. For the brevity of the specification, the description of conventional electronic configurations, control systems, software, and other functional aspects of the systems may be omitted. Connections of lines or connection members between components shown in the drawings are illustrative of functional connections and/or physical or circuit connections, and in practice, may be represented as alternative or additional various functional connections, physical connections, or circuit connections.

The use of the terms of “the above-described” and similar indicative terms may correspond to both the singular forms and the plural forms.

Also, operations constituting a method may be performed in any suitable order unless it is explicitly stated that they should be performed in an order they are described. Also, the use of all exemplary terms (for example, etc.) is only to describe technical spirit in detail, and the scope of rights is not limited by these terms unless limited by the claims.

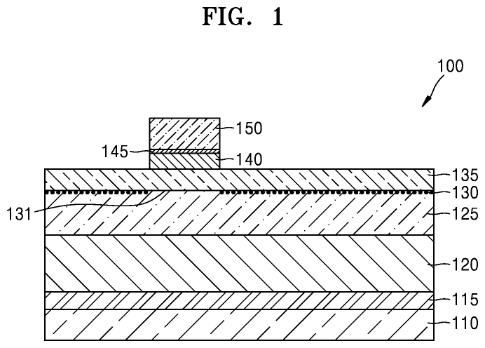

FIG. 1 is a cross-sectional view of a high electron mobility transistor (HEMT) according to an embodiment.

An HEMT 100 may include a substrate 110, a channel layer 125, a barrier layer 135, a p-type gallium nitride (GaN) layer 140, and a gate electrode 150. An n-type interfacial layer 145 may be provided between the p-type GaN layer 140 and the gate electrode 150. The n-type interfacial layer 145 may directly contact the p-type GaN layer 140. The n-type interfacial layer 145 may directly contact the gate electrode 150.

The substrate 110 may include at least one of silicon (Si), silicon on insulator (SOI), silicon carbide (SIC), or GaN. The channel layer 125 may include a group III-V compound semiconductor, for example, GaN, indium GaN (InGaN), or aluminum GaN (AlGaN). However, without being limited thereto, the channel layer 125 may include a material that is different from a semiconductor layer as long as a material allows formation of two-dimensional electron gas (2DEG). A GaN-based semiconductor has a large energy band gap and superior physical properties such as high thermal and chemical stability, high electron saturation rate (˜3×10⁷ cm/sec, etc.).

Thus, the GaN-based semiconductor is applicable as not only an optical device, but also a high-frequency and high-output electronic device. An electronic device using the GaN-based semiconductor may have various characteristics such as a high breakdown field (˜3×10⁶ V/cm), a high maximum current density, a stable high-temperature operating feature, a high thermal conductivity, etc. In the case of an HEMT using a GaN-based heterojunction structure, band discontinuity between a channel layer and a channel supply layer is large, causing electrons to be concentrated on a bonding interface at a high concentration and thus improving electron mobility.

A buffer layer 120 may be further provided between the substrate 110 and the channel layer 125. The buffer layer 120 may include a group III-V compound semiconductor.

The buffer layer 120 may be provided to prevent degradation of crystallinity of the channel layer 125 by mitigating differences in the lattice constant and the thermal expansion coefficient between the substrate 110 and the channel layer 125. The buffer layer 120 may include, for example, aluminum nitride (AlN), AlGaN, aluminum indium nitride (AlInN), or aluminum indium gallium nitride (AlInGaN). The buffer layer 120 may be formed as one layer or a plurality of layers. In some cases, a seed layer 115 may be further provided between the substrate 110 and the buffer layer 120. The seed layer 115 may be a layer utilized for growth of the buffer layer 120. The seed layer 115 may include AlN. The substrate 110, the seed layer 115, and the buffer layer 120 may be removed after manufacturing the HEMT 100. That is, in the HEMT 100, the substrate 110, the seed layer 115, and the buffer layer 120 may be selectively provided.

The barrier layer 135 may include the group III-V compound semiconductor. The barrier layer 135 may include a nitride including, for example, at least one of Al, Ga, or In, and may have a single-layer or multi-layer structure.

The barrier layer 135 may include any one of AlN, AlGaN, AlInN, AlGaInN, or a combination thereof. The barrier layer 135 may be doped as an n type. The barrier layer 135 may include a material having a polarization feature different from that of the channel layer 125. The barrier layer 135 may be formed of a material having a band gap larger than that of the channel layer 125. Although it is shown in FIG. 1 that the barrier layer 135 includes one layer, the barrier layer 135 may also include a plurality of layers.

A two-dimensional electron gas (2DEG) layer 130 may be provided in a part of the channel layer 125. In the channel layer 125, the 2DEG layer 130 may be formed by spontaneous polarization P_{SP} and Piezo polarization PPE caused by tensile strain.

The p-type GaN layer 140 may be provided on the barrier layer 135. The p-type GaN layer 140 may be provided between the barrier layer 135 and the gate electrode 150 to make a normally-off state in which current does not flow between a drain electrode and a source electrode for a gate voltage of 0 V.

The n-type interfacial layer 145 may include a nitrogen-vacancy (NV) enriched layer. The n-type interfacial layer 145 may include a nitrogen vacancy such that GaN becomes an n-type layer. By performing high-temperature heat treatment on the p-type GaN layer 140 and the barrier layer 135, a nitrogen atom may move from the p-type GaN layer 140 to the barrier layer 135, such that a nitrogen vacancy may occur on an interface between the p-type GaN layer 140 and the barrier layer 135, and thus the n-type interfacial layer 145 may become an n-type layer. The n-type interfacial layer 145 may have a thickness of about 1 nm to about 5 nm. Alternatively, the n-type interfacial layer 145 may have a thickness of about 1 nm to about 3 nm.

The n-type interfacial layer 145 and the gate electrode 150 may constitute a Schottky contact.

Furthermore, the p-type GaN layer 140, the n-type interfacial layer 145, and the gate electrode 150 may be formed at a position on the barrier layer 135 corresponding to an opening/gap 131 of the 2DEG layer 130 (i.e., at a position where the 2DEG layer 130 is not formed).

As described above, the HEMT 100 according to an embodiment may increase a Schottky barrier for a hole by including the n-type interfacial layer 145 in the p-type GaN layer 140, thereby reducing a forward gate leakage current. The HEMT 100 according to an embodiment may be applied to a power conversion system such as alternate-direct, direct-alternate, direct-direct, etc., to control flow of current through on/off switching. A device used for switching is a power semiconductor such as a power metal-oxide-semiconductor field-effect transistor (MOSFET), an insulated gate bipolar transistor (IGBT), a bipolar junction transistor (BJT), a Schottky barrier diode (SBD), etc., and the HEMT 100 according to an embodiment may improve the reliability of the power semiconductor.

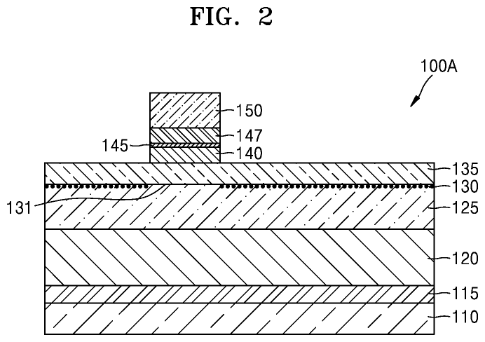

FIG. 2 is a cross-sectional view an example of the high electron mobility transistor of FIG. 1 that further includes a silicon nitride layer according to an embodiment

FIG. 2 shows an example where a silicon nitride (SiN) layer 147 is further included in the high electron mobility transistor shown in FIG. 1. In FIG. 2, a component using the same reference numeral as in FIG. 1 is substantially the same as described with reference to FIG. 1 and repeated descriptions may be omitted.

An HEMT 100A may include a SiN layer 147 provided between the n-type interfacial layer 145 and the gate electrode 150.

The SiN layer 147 may have a silicon-rich composition. That is, the SiN layer 147 may have a composition with a composition ratio of silicon and nitrogen, which is greater than 1. When the SiN layer 147 is expressed as SiN, (Si/N) may be greater than 1. The SiN layer 147 may have a thickness of about 1 nm to about 500 nm. The n-type interfacial layer 145 may be formed by performing high-temperature heat treatment on the SiN layer 147. This will be described in more detail in the method of manufacturing the high electron mobility transistor.

Furthermore, the p-type GaN layer 140, the n-type interfacial layer 145, the SiN layer 147, and the gate electrode 150 may be formed at a position on the barrier layer 135 corresponding to an opening/gap 131 of the 2DEG layer 130 (i.e., at a position where the 2DEG layer 130 is not formed).

In a power conversion system, the efficiency of the entire system may depend on the efficiency of a switching device. A silicon-based power MOSFET or IGBT is widely used as a power device, but there is a limit to increasing the efficiency of the power device due to material limitations of silicon. To overcome such limitations, power conversion efficiency may be increased by manufacturing a transistor using a gallium nitride semiconductor instead of silicon. When a gate voltage is 0 V, to enter a normally off state where current does not flow between a drain electrode and a source electrode, a structure in which the p-type GaN layer 140 is grown on the channel layer 125 and the barrier layer 135 is used. The p-type GaN layer 140 may be etched to form the other region than a region corresponding to the gate electrode 150 as a drift region.

The HEMT according to an embodiment may use a Schottky gate and need to reduce a gate leakage current for reliability of the device. To reduce the gate leakage current, plasma treatment, heat treatment, gate metal work function adjustment, etc., may be mainly used, and for example, plasma treatment may cause a damage due to plasma with a high bias voltage. However, according to an embodiment, a Schottky barrier for a hole may be increased using the p-type GaN layer 140 and the n-type interfacial layer 145, thereby reducing a forward gate leakage current.

Manufacturing of the HEMT may include a gate-first process of forming a gate electrode first before an ohmic process and an ohmic-first process of performing the ohmic process before a gate electrode process. In the gate-first process, the HEMT may have a self-aligning gate structure where the p-type GaN layer 140, the n-type interfacial layer 145, and the gate electrode 150 are etched in sequence. Each of the p-type GaN layer 140 and the gate electrode 150 may directly contact the n-type interfacial layer 145. In the self-aligning gate structure, it is easy to control a line width and the number of photomasks, and process operations in a manufacturing process may be reduced, thereby reducing production cost.

The p-type GaN layer 140 may increase a size of a barrier for electron conduction to or from an interface between the channel layer 125 and the barrier layer 135, thereby implementing the normally off state.

In the gate-first process, the ohmic process requiring high temperature may be performed after the gate electrode process, and as such, the gate electrode 150 may include a material capable of enduring high-temperature ohmic heat treatment. The gate electrode 150 may include at least one of, for example, Ti, TiN, TiAl, or W.

The HEMT according to an embodiment may be applied to high power, a high-integration transistor, a switch, a power amplifier, a microwave monolithic integrated circuit (MMIC), etc., by heterojunction of a group III-V compound semiconductor.

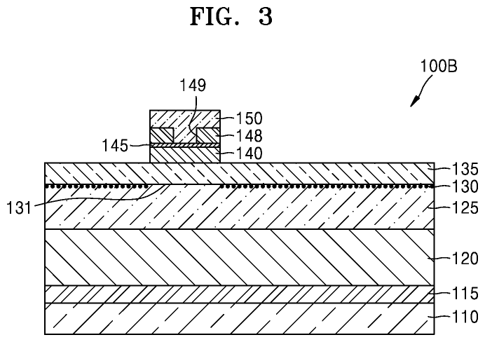

FIG. 3 is a cross-sectional view of a modified example of the silicon nitride layer of FIG. 2 according to an embodiment.

Referring to FIG. 3, an HEMT 100B may include a SiN layer 148 which may include a through-hole 149. The gate electrode 150 may extend to the through-hole 149. By opening the SiN layer 148 via the through-hole 149 and depositing the gate electrode 150 to the through-hole 149, a Schottky barrier for a hole may be increased, thereby effectively reducing the forward gate leakage current.

Furthermore, the p-type GaN layer 140, the n-type interfacial layer 145, the SiN layer 148, the through-hole 149 and the gate electrode 150 may be formed at a position on the barrier layer 135 corresponding to an opening/gap 131 of the 2DEG layer 130 (i.e., at a position where the 2DEG layer 130 is not formed). That is, the p-type GaN layer 140, the n-type interfacial layer 145, the SiN layer 148, the through-hole 149 and/or the gate electrode 150 may have a width corresponding to the width of the opening 131.

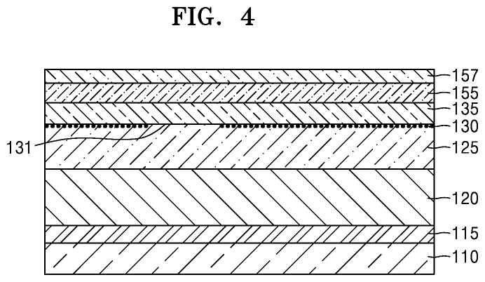

FIGS. 4, 5, 6, 7 and 8 are cross-sectional views illustrating a method of manufacturing a high electron mobility transistor according to an embodiment.

Referring to FIG. 4, the channel layer 125 may be deposited on the substrate 110 and the barrier layer 135 may be deposited on the channel layer 125. A deposition process may include physical vapor deposition or chemical vapor deposition. The seed layer 115 and the buffer layer 120 may be further deposited between the substrate 110 and the channel layer 125. A 2DEG layer 130 may be formed on the channel layer 125 and may include a gap/opening 131. A reserved p-type GaN layer 155 may be deposited on the barrier layer 135, and a reserved SiN layer 157 may be deposited on the reserved p-type GaN layer 155. The reserved SiN layer 157 may be a silicon-rich layer and have a composition ratio of silicon and nitrogen, which is greater than 1. Then, the reserved SiN layer 157 may be heat-treated at high temperature.

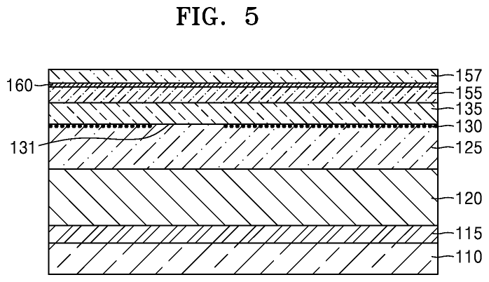

Referring to FIG. 5, a reserved n-type interfacial layer 160 may be formed between the reserved p-type GaN layer 155 and the reserved SiN layer 157 by heat treatment. Heat treatment may be performed at a temperature of about 400° ° C. or higher. As a nitrogen atom spreads to the reserved SiN layer 157 from the reserved p-type GaN layer 155, a nitrogen vacancy may be generated in an interface between the reserved p-type GaN layer 155 and the reserved SiN layer 157, and a reserved n-type interfacial layer 160 having become an n-type layer may be formed by the nitrogen vacancy. Thus, the reserved n-type interfacial layer 160 may be formed as a nitrogen vacancy-enriched layer. Then, the reserved SiN layer 157 may be removed. Removal of the reserved SiN layer 157 may be selective. After the reserved SiN layer 157 is removed, the reserved p-type GaN layer 155 and the reserved n-type interfacial layer 160 may be etched to form the p-type GaN layer 140 and the n-type interfacial layer 145. When the gate electrode 150 is deposited on the n-type interfacial layer 145, the HEMT 100 shown in FIG. 1 may be formed.

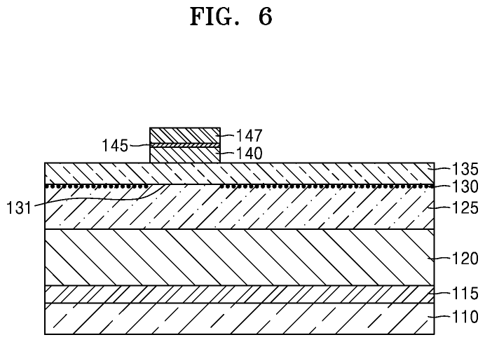

Alternatively, as shown in FIG. 6, etching may be performed in a state where the reserved SiN layer 157 is not removed, such that the p-type GaN layer 140, the n-type interfacial layer 145, and the SiN layer 147 may be sequentially deposited and the gate electrode 150 may be deposited on the SiN layer 147, thereby forming the HEMT 100A shown in FIG. 2. The p-type GaN layer 140, the n-type interfacial layer 145, and the SiN layer 147 may be etched to have the same width. The width of the p-type GaN layer 140, the n-type interfacial layer 145, and the SiN layer 147, may correspond to a region 131 (e.g., the gap/opening 131) where the 2DEG layer 130 is not formed.

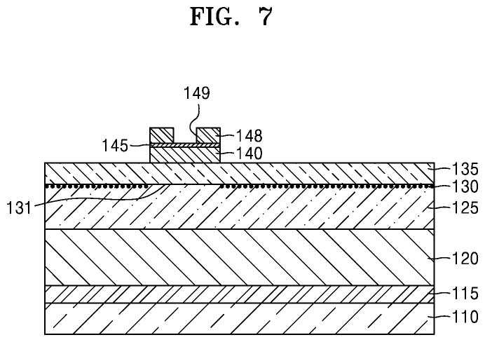

Referring to FIG. 7, the through-hole 149 may be formed by etching the SiN layer 148 in a structure shown in FIG. 6. A part of the n-type interfacial layer 145 may be exposed by etching the SiN layer 148. By depositing the gate electrode on the SiN layer 148 in which the through-hole 149 is formed, the HEMT 100B shown in FIG. 3 may be formed.

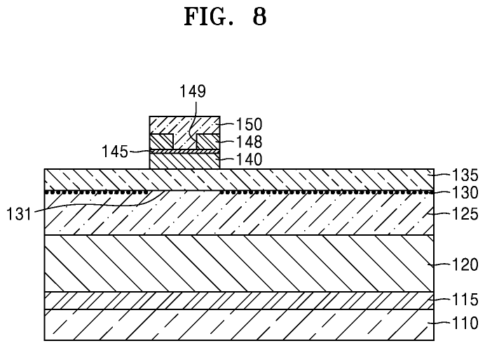

Referring to FIG. 8, a gate electrode 150 may be deposited on the SiN layer 148 and in the through-hole 149. The gate electrode 150 may also have a width corresponding to the width of the region 131 where the 2DEG layer 130 is not formed (e.g., an opening 131 in the 2DEG layer 130).

As described above, according to an embodiment, a manufacturing method for forming the n-type interfacial layer 145 on the p-type GaN layer 140 may be provided.

While the HEMT according to the embodiment has been shown and described with reference to the embodiment to help understanding of the disclosure, it will be apparent to those of ordinary skill in the art that modifications and variations may be made. Therefore, the true technical scope of the disclosure should be defined by the appended claims.

The HEMT according to an embodiment may reduce the gate leakage current due to including the n-type interfacial layer between the p-type GaN layer and the gate electrode. The method of manufacturing the HEMT according to an embodiment may include forming the n-type interfacial layer by performing high-temperature heat treatment on the SiN layer.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A high electron mobility transistor (HEMT), comprising:
a substrate;
a channel layer on the substrate;
a barrier layer on the channel layer;
a p-type gallium nitride (GaN) layer on the barrier layer;
an n-type interfacial layer on the p-type GaN layer; and
a gate electrode on the n-type interfacial layer.

2. The HEMT of claim 1, wherein the n-type interfacial layer comprises a nitrogen vacancy.

3. The HEMT of claim 1, wherein the n-type interfacial layer comprises a thickness of about 1 nm to about 5 nm.

4. The HEMT of claim 1, wherein the n-type interfacial layer directly contacts the p-type GaN layer.

5. The HEMT of claim 1, wherein the n-type interfacial layer and the gate electrode form a Schottky contact.

6. The HEMT of claim 1, further comprising a silicon nitride (SiN) layer between the n-type interfacial layer and the gate electrode.

7. The HEMT of claim 6, wherein the SiN layer comprises a composition ratio of silicon to nitrogen that is greater than 1.

8. The HEMT of claim 6, wherein the SiN layer comprises a thickness of about 1 nm to about 500 nm.

9. The HEMT of claim 1, wherein the gate electrode comprises at least one of titanium (Ti), titanium nitride (TiN), titanium aluminide (TiAl), or tungsten (W).

10. The HEMT of claim 1, wherein the channel layer comprises gallium nitride (GaN), indium gallium nitride (InGaN), or aluminum gallium nitride (AlGaN).

11. The HEMT of claim 1, wherein the barrier layer comprises aluminum nitride (AlN), AlGaN, aluminum indium nitride (AlInN), or aluminum indium gallium nitride (AlInGaN).

12. A method of manufacturing a high electron mobility transistor (HEMT), the method comprising:
depositing a channel layer on a substrate;
depositing a barrier layer on the channel layer;
depositing a p-type gallium nitride (GaN) layer on the barrier layer;
depositing a silicon nitride (SiN) layer on the p-type GaN layer;
forming an n-type interfacial layer between the p-type GaN layer and the SiN layer by performing heat treatment on the SiN layer; and
forming a gate electrode on the n-type interfacial layer.

13. The method of claim 12, wherein the heat treatment is performed at a temperature of about 400° C. or higher.

14. The method of claim 12, wherein the n-type interfacial layer comprises a nitrogen vacancy.

15. The method of claim 12, wherein the n-type interfacial layer comprises a thickness of about 1 nm to about 5 nm.

16. The method of claim 12, wherein the n-type interfacial layer directly contacts the p-type GaN layer.

17. The method of claim 12, further comprising, prior to the forming of the gate electrode, removing the SiN layer.

18. The method of claim 12, further comprising forming a through-hole through which the p-type GaN layer is exposed by partially etching the SiN layer.

19. A high electron mobility transistor (HEMT), comprising:
a substrate;
a channel layer on the substrate;
a barrier layer on the channel layer;
a two-dimensional electron gas (2DEG) layer formed between the channel layer and the barrier layer,
a p-type gallium nitride (GaN) layer on the barrier layer;
an n-type interfacial layer on the p-type GaN layer; and
a gate electrode on the n-type interfacial layer.

20. The HEMT of claim 19, wherein the 2DEG layer comprises an opening, and
wherein a width of at least one of the p-type GaN layer, the n-type interfacial layer, or the gate electrode corresponds to a width of the opening of the 2DEG layer.
